(19) United States
(12) Patent Application Publication
(10) Pub. No.: US 2026/0236089 A1
(43) Pub. Date: Aug. 13, 2026

(54) DEVICE FOR THE INTERACTION OF A USER WITH A SIMULATION ENVIRONMENT

(71) Applicant: SimVenture GmbH, Grieskirchen (AT)

(72) Inventor: Norman Eisenköck, Grieskirchen (AT)

(21) Appl. No.: 19/156,872

(22) PCT Filed: Oct. 18, 2023
(86) PCT No.: PCT/AT2023/060358

§ 371 Date: Aug. 14, 2025

(30) Foreign Application Priority Data
Feb. 16, 2023 (AT) A 50104/2023

(51) Int. Cl. G06F 3/01

(52) U.S. Cl. CPC G06F 3/011; G06F 3/016

(57) ABSTRACT

A device for the interaction between a user (2) and a simulation environment comprises a bearing element (1) for the user (2), which bearing element (1) is connected via at least one drive means (3) to at least one actuator (4), a detection unit for control data and a computing unit (5) connected to the detection unit for controlling the actuators (1). A user can interact authentically with the simulation environment, taking into account the movement of their entire body. A plurality of bearing elements (1) are provided for different limbs of the user (2), each of which bearing elements (1) is connected to two actuators (4) via drive means (3), wherein the direction of the force exertable by at least one actuator (4) on the respective bearing element (1) deviates from a direction opposite to the direction of gravity (8)

### FIELD OF THE INVENTION

The invention relates to a device for the interaction between a user and a simulation environment, comprising a bearing element for the user, which bearing element is connected via at least one drive means to at least one actuator, a detection unit for control data and a computing unit connected to the detection unit for controlling the actuators.

### DESCRIPTION OF THE PRIOR ART

Motion control devices for the interaction between a user and a simulation environment are known from the prior art, in which a suspension is connected to a simulation suit for a user (US2021228993A1). The suspension engages with the user's torso via an adapter provided with several pull ropes so that the user can be pulled up and brought into a suspended position. Cameras detect the position of the user, whereupon the pull ropes are activated to cause the torso to move depending on the user's movements. In this way, the simulation environment of a parachute jump or skydive can be simulated.

A similar device is known from US20130109484A1, but it does not have a camera for position detection.

KR1020190047311A and EP3552970A1 also show similar devices, wherein in KR1020190047311A compressed air is directed via guide elements to the extremities of the user and in EP3552970A1 the entire user is blown with compressed air from below in order to make certain simulation environments more realistic.

The flight simulator of KR1020180077518A also shows a wingsuit-like adapter suspended above pulleys.

US20230032506A1 shows a carrying device for fairground vehicles, which is suspended by several cables acting against the direction of gravity, which form parts of a pulley block.

However, a disadvantage of the prior art is that the forces that can be exerted by the motion control system on the user for interaction with the simulation environment are limited, since the suspension can only exert vertical forces on the user's torso that counteract the force of gravity. This severely limits the variety and complexity of the environments that can be simulated and, consequently, their degree of authenticity.

### SUMMARY OF THE INVENTION

The invention is therefore based on the task of enabling a user to interact authentically with the simulation environment, taking into account the movement of his entire body.

The invention solves the problem by providing a plurality of bearing elements for different limbs of the user, each of which bearing elements is connected to two actuators via drive means, whereby the direction of the force exertable by at least one actuator on the respective bearing element deviates from a direction opposite to the direction of gravity.

The invention is based on the idea that the user interacts with the simulation environment via forces exerted on the user's limbs and vice versa. According to the invention, this is implemented in a manner in that the device according to the invention can exert forces on the individual limbs in a control loop, the force vectors of which forces have different spatial directions of action and do not only counteract the gravitational force in an antiparallel manner. A detection unit is provided for the control loop to detect control data, which the computing unit uses to control the actuators. For example, the detection unit may comprise a camera that detects the change in the spatial position of the user as control data, whereupon the computing unit controls one or more actuators on the basis of this control data in order to exert forces on the individual limbs of the user in the sense of a control loop, whereby the forces per limb may differ from one another. For example, the device according to the invention can be used to perform swimming or diving movements if bearing elements are provided on the user's arms and legs, since this allows the different water resistance of each limb to be simulated during a lateral swimming movement of the user. The force that can be exerted on a bearing element is, in vector terms, the resultant force of the forces exerted by the two actuators via the drive means. Since the force vectors of the forces that can be exerted on the bearing elements generally run along the drive means, the directions of the resultant forces that can be exerted can be determined by the arrangement of the drive means and/or the actuators. In a preferred embodiment, the two actuators and the bearing element connected to them can be arranged at the corners of a fictitious triangle, with the two drive means forming two of the three sides of this triangle. Due to this triangular arrangement, the two forces exerted on the bearing element by the actuators are linearly independent in their direction, which allows for a large number of possible force directions. The actuators can be rope winches that roll ropes up and down as drive means. The bearing elements can, for example, be loops that are placed around the user's limbs. In a preferred embodiment, the bearing elements are arranged on a simulation suit that the user puts on. In order to make the simulation environment even more realistic, an optical output, for example virtual reality glasses, can be provided for the user, which is also controlled by the computing unit. In the sense of the invention, the force exerted by the device on the user is always understood to be an active force exerted on the basis of the control of the actuators. This means that the force exerted by the device acts on the user in addition to a passive force, i.e., a force that would also act on the user in the absence of the device, such as the force of gravity. For example, the acceleration of a bearing element solely due to the gravitational force caused by the idling of the actuators assigned to it is not understood as a force exerted. Although it is self-evident to the skilled person that a force is by nature a vector quantity and not a scalar quantity, it should be expressly pointed out once again that the terms “force” and “force vector” are used synonymously.

In addition to the bearing elements, a support element may be provided to transfer most of the user's body weight into the device. This support element may preferably be arranged in the area of the user's center of gravity and may also be connected to one or more actuators via one or more drive means. Due to the fact that the support element absorbs most of the user's body weight, the bearing elements according to the invention have to absorb comparatively lower forces and can therefore not only be smaller in size, but also react more quickly due to the lower mass.

The spatial detection of the user or the bearing elements is imprecise and error-prone if it is performed optically without complex technical means, which impairs the quality of the control data. In order to be able to determine precise control data quickly using technically simple means, it is therefore proposed that the detection unit comprises a plurality of position transmitters, each assigned to an actuator, for detecting its position travel as control data. As a result of these measures, the easily determinable position travel of the actuator, for example the deflection of a linear motor or the rolling status of a cable winch, can be determined as control data. This control data can be processed in the computing unit, thereby determining the position of the user and, consequently, the forces to be exerted. From these state variables, the relative position of the user can be easily determined, for example. Preferably, the device is calibrated before the user starts interacting with the simulation environment, as this also allows the absolute position of the user to be determined in a defined coordinate system. This can be done, for example, by defining a start position for the user and then resetting all state variables to zero.

If, in the simulation environment, a force is to be exerted quickly and easily by the device on the user in response to a force exerted by the user, this can be implemented by technically simple means analogous to the detection of the position travel by the detection unit comprising a plurality of actuator force transducers, each assigned to an actuator, for detecting the actuator force as control data. In this case, the forces exerted by the user on the actuator are determined as actuator forces by the actuator force transducer as control data and processed analogously to the above. This enables, for example, the simulation of a swimming movement as described above: If the actuator force transducer registers a swimming movement in the actuators assigned to the arms, the forces exerted by this swimming movement serve as control data, which are detected via the actuator force transducer, and the computing unit determines the counterforces to be exerted by the actuators on the user, which counterforces simulate the water resistance.

Even if the control variables determined at the actuator can be determined simply and accurately, some simulation environments require control data that cannot be determined via the actuator. In order to determine such control data nevertheless, or to obtain correction data for limbs to which a bearing element is assigned, it is proposed that the detection unit comprises an optical recording device for determining the spatial position of at least one part of the user's body as control data. As a result of these measures, body parts or movements that cannot be detected by a position transmitter or an actuator force transducer can also be detected, such as the position of body parts for which no bearing element is provided, or rotational movements of body parts. The spatial position detected in this way can be fed to the computing unit as control data. Alternatively or additionally, control data obtained in this way can be used as a correction to the control data detected via the actuator, for example via a position transmitter or an actuator force transducer.

In order to implement a simulation environment in which gravity is higher than Earth's gravity, at least one actuator of a bearing element can be arranged such that the force it exerts on the bearing element comprises a component running in the direction of gravity. As a result of these measures, a force can be exerted on the bearing element which comprises a force component parallel to the gravitational vector and thereby amplifies the gravitational force. In a particularly space-saving and easy-to-control embodiment, both actuators and the bearing element lie on a fictitious line bounded by the actuators, so that the drive means of both actuators run parallel to the gravitational vector.

In order to enable movement of the body members without the influence of active forces transverse to the gravitational vector without having to actuate an actuator, it is proposed that at least one actuator is mounted on a support platform so that it can be displaced transverse to the gravitational vector. This allows the user to move the actuators transversely to the gravitational vector, i.e. horizontally, without them having to compensate for this lateral movement by means of an adjustment path. The support platform also has the advantage that the actuators and any support element can be easily mounted. The actuators can be mounted passively, i.e. without any further drive, so that they follow the movement of the body member due to the tensile forces exerted by the user on the actuator. In a preferred embodiment, however, the actuators are mounted so that they are actively mounted, i.e., they have a drive with which they can be moved. This allows a further force to be exerted on the user via this drive. More preferably, this drive can be switched to idle, which allows movement as with passive mounting.

If a support platform is used, it may not be possible to mount all actuators on it in order to achieve a large number of possible forces that can be exerted. However, if two support platforms, which opposite each other with respect to the bearing elements, are provided for mounting at least one actuator, the actuators can be distributed across both support platforms, which increases the possibilities for their spatial arrangement and thus the number of forces that can be exerted. A symmetrical arrangement still allows relatively simple control of the actuators to generate the desired resulting forces.

In order to enable the user to perform rolling, pitching, and/or yawing movements, it is proposed that at least one support platform be mounted so as to be pivotable about a pivot axis. In this way, the actuators of a support platform can be pivoted together and simultaneously with the support platform, causing the entire body of the user to be displaced. Although these movements can also be achieved without a pivotable support platform if the actuators or drive means are arranged accordingly, but if according to the invention, the support platform is pivotably mounted, the actuators do not have to be controlled separately, which simplifies the control of the device. If two support platforms are provided, both are preferably pivotable about a common axis.

The invention also relates to a method for operating a device as described above for the interaction of a human body with a simulation environment, wherein the computing unit determines setpoint values for the actuators on the basis of the control data and a kinematic model assigned to the simulation environment, whereupon the actuators are controlled on the basis of these setpoint values. The computing unit receives the control data from the detection unit and thus the information about the position or forces acting on the bearing elements and possibly other parts of the user's body. The kinematic model represents the relevant physical relationships and laws prevailing in the simulation environment so that the computing unit can determine how an action of the user in the simulation environment affects the user and what counterforces, if any, should act on the user. For example, the kinematic model can comprise a vector field that assigns a vector to every point in space where the user can move in the simulation environment. In the simplest case, an environment with low gravity can be simulated by assigning a force vector counteracting the gravitational vector to every point in space. Based on the information obtained from the control data about the position of a bearing element and by retrieving the setpoint value assigned to this point, the computing unit can now determine a corresponding force to be exerted on the bearing element and control the respective actuators so that this force is exerted on the bearing element. In general, the kinematic model can be used to assign the forces recorded as control data to a resulting position travel as a setpoint value for one or more actuators.

### BRIEF DESCRIPTION OF THE INVENTION

The drawing shows an example of the invention, wherein

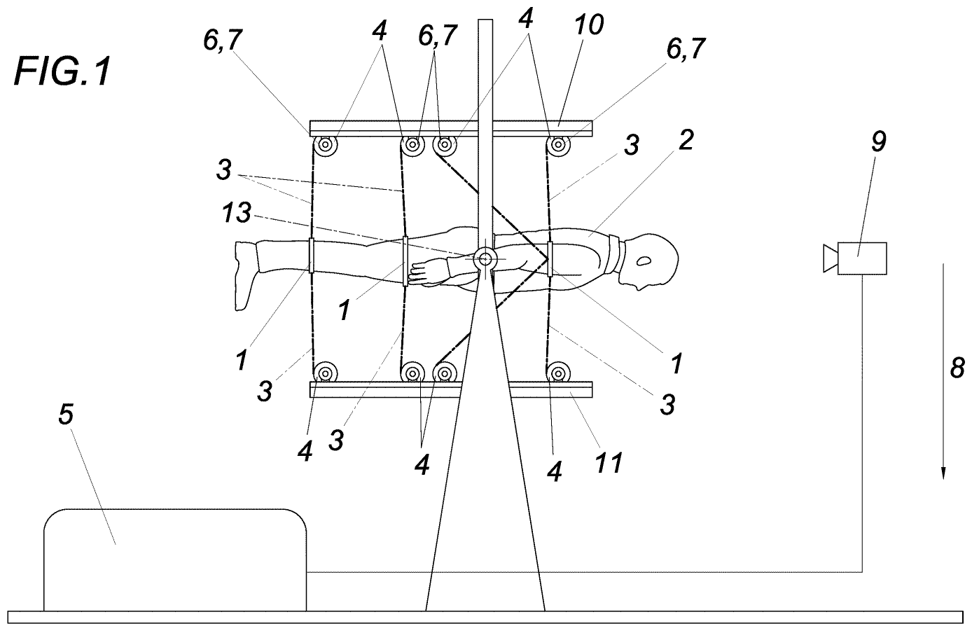

FIG. 1 shows a schematic side view of a device according to the invention with a user,

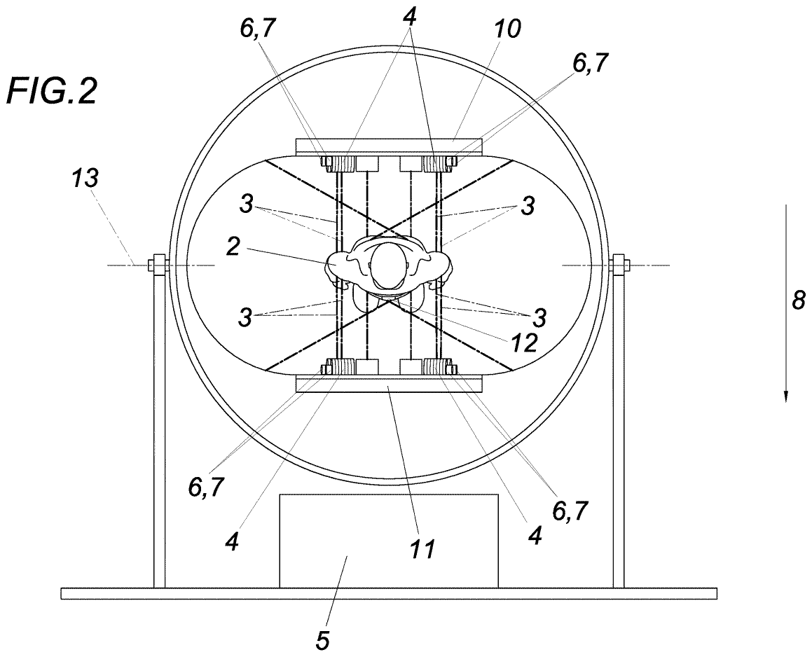

FIG. 2 shows a schematic front view of the device according to the invention of FIG. 1.

### DESCRIPTION OF THE PREFERRED EMBODIMENTS

A device according to the invention comprises a plurality of bearing elements 1, via which forces are exerted by and on the user 2 in order to interact with the simulation environment and which are provided for several limbs of the user 2. The bearing elements 1 are connected to actuators 4 via drive means 3. In the embodiment shown, the bearing elements 1 are loops which the user 2 wears around the limbs. In order to determine which forces are to be exerted on the user 2 by the device as a function of his position or his movements relative to the device, a detection unit is provided, which detects the control data and, on the basis of this control data and a kinematic model assigned to the simulation environment, determines setpoint values for the actuators 4, on the basis of which setpoint values a computing unit 5 controls the actuators 4. In the embodiment shown, the actuators 4 are rope winches which roll ropes up and down as drive means 3. The detection unit comprises position transmitters 6 and actuator force transducers 7, which comprise the position travel or the actuator force of the actuators 4 as control data and, in the embodiment shown, are arranged in housings mounted concentrically with the rope winches.

In order to exert forces on the user 2 which deviate in their orientation from a direction antiparallel to the direction of gravity 8, two actuators 4 are provided for each of a plurality of bearing elements 1, wherein in the embodiments shown, a drive means 3 is also provided for each actuator 4. The arrangement of the actuators 4 and drive means 3 shown in the embodiments shown allows some limbs to be pulled down in the direction of gravity 8, since the force exerted on these limbs includes a component running in the direction of gravity 8. Other bearing elements 1 can be displaced transversely to the direction of gravity 8 by providing actuators 4 for these bearing elements 1, which are arranged with the bearing element 1 in a triangle so that linearly independent force vectors can be exerted on these bearing elements 1.

For realistic representation of some simulation environments, the control data detected by the detection unit via the bearing elements 1 is not sufficient, which is why the detection unit can comprise an optical recording device 9, in the embodiments shown a camera, which determines the spatial position of at least one body part of the user 2. For reasons of perspective, the camera is only shown in FIG. 1. This body part may also be limbs, but it may also be, for example, the torso of the user 2. This allows the force to be exerted on the user 2 via the bearing elements 1 to also be regulated by control data that is not obtained via the bearing elements 1.

In the embodiment shown, the actuators 4 are arranged on a support platform 10, whereby the actuators 4 can be displaced transversely to the direction of gravity 8. The actuators 4 can be mounted on rails on the support platform or, preferably, on a cross slide, so that the actuators 4 can be displaced by the force exerted by the user 2. Preferably, active drive means are provided for the actuators 4 so that a force component acting transversely to the gravitational vector 8 can also be exerted via the actuators 4 on the bearing elements 1 associated with the actuators 4. In order to increase the positioning options of the actuators 4 or drive means 3 and thus enable a greater variety of forces to be exerted, two support platforms 10, 11 may be provided, which are opposite each other with respect to the bearing elements 1.

As can be seen in FIG. 2, in the embodiment shown, a support element 12 is provided in the area of the user's center of gravity, via which the majority of the body weight of the user 2 can be transferred into the device, so that not the entire body weight has to be transferred into the device via the bearing elements 1.

In the embodiment shown, both support platforms 10, 11 are pivotably mounted about the pivot axis 13 so that pitching movements can be realized via the support platforms 10, 11.

1. A device for interaction between a user and a simulation environment, said device comprising:
a plurality of bearing elements each being configured to interact with a respective one of limbs of the user and each being connected to two actuators via respective drive means;
a detection unit deriving control data; and
a computing unit connected to the detection unit and controlling the actuators; and
wherein at least one actuator exerts force on the respective bearing element in a direction that deviates from a direction opposite to a direction of gravity.

2. The device according to claim 1, wherein a support element transfers most of a body weight of the user into the device.

3. The device according to claim 1, wherein the detection unit comprises a plurality of position transmitters each assigned to a respective actuator detecting a respective position travel as a portion of the control data.

4. The device according to claim 1, wherein the detection unit comprises a plurality of actuator force transducers, each assigned to a respective actuator and detecting actuator force of the actuator as a portion of the control data.

5. The device according to claim 1, wherein the detection unit comprises an optical recording device determining a spatial position of at least one body part of the user as a portion of the control data.

6. The device according to claim 1, wherein at least one actuator of a one of the bearing elements is arranged such that the force exerted thereby on the bearing element comprises a component in the direction of gravity.

7. The device according to claim 1, wherein at least one actuator is mounted on a support platform so as to be displaceable transversely to the direction of gravity.

8. The device according to claim 1, wherein two support platforms opposite each other with respect to the bearing elements support at least one actuator.

9. The device according to claim 7, wherein the support platform is mounted so as to be pivotable about a pivot axis.

10. A method for operating a device according to claim 1, wherein the computing unit determines setpoint values for the actuators on based on the control data and a kinematic model assigned to the simulation environment, whereupon the actuators are controlled based on the setpoint values.

11. The device according to claim 1, wherein the computing unit determines setpoint values for the actuators based on the control data and a kinematic model assigned to the simulation environment, and the actuators are controlled based on the setpoint values.

12. The device according to claim 2, wherein the detection unit comprises a plurality of position transmitters each assigned to a respective actuator detecting a respective position travel as a portion of the control data.

13. The device according to claim 2, wherein the detection unit comprises a plurality of actuator force transducers, each assigned to a respective actuator and detecting actuator force of the actuator as a portion of the control data.

14. The device according to claim 3, wherein the detection unit comprises a plurality of actuator force transducers, each assigned to a respective actuator and detecting actuator force of the actuator as a portion of the control data.

15. The device according to claim 2, wherein the detection unit comprises an optical recording device determining a spatial position of at least one body part of the user as a portion of the control data.

16. The device according to claim 3, wherein the detection unit comprises an optical recording device determining a spatial position of at least one body part of the user as a portion of the control data.

17. The device according to claim 4, wherein the detection unit comprises an optical recording device determining a spatial position of at least one body part of the user as a portion of the control data.

18. The device according to claim 8, wherein at least one of the support platforms is mounted so as to be pivotable about a pivot axis.
